(19) United States
(12) Patent Application Publication
(10) Pub. No.: US 2005/0285261 A1
(43) Pub. Date: Dec. 29, 2005

(54) Thermal management arrangement with channels structurally adapted for varying heat flux areas

(76) Inventors: Ravi S. Prasher, Tempe, AZ (US); Chia-Pin Chiu, Tempe, AZ (US); Himanshu Pokharna, San Jose, CA (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/877,925

(22) Filed: Jun. 25, 2004

(51) Int. Cl. H01L 23/34

(52) U.S. Cl. 257/718

(57) ABSTRACT

An apparatus, method, and system for a thermal management arrangement for cooling semiconductor packages with channels structurally adapted for varying heat flux areas.

### FIELD

Disclosed embodiments of the present invention relate to the field of thermal management, and more particularly to a thermal management arrangement with channels structurally adapted for varying heat flux areas.

### BACKGROUND

Thermal management is of great importance to the operation of semiconductor devices. Thermal management is especially important in the operation of microprocessors as relentlessly increasing frequency targets push power output, and therefore heat generation, to the limits of the cooling capacity of passive air-cooled heatsink technology. Insufficient transfer of heat away from a semiconductor device can result in degradation in performance and reliability of that device or circuit.

Recent focus has turned to thermal management arrangements utilizing liquid flowing through parallel channels to dissipate heat. The channels each have similar dimensions and each have an input to receive fluid from a common inlet coupled to a remote pump, and an output to transmit the fluid to a common outlet towards a heat exchanger. This design does not fully account for across die temperature gradients that may result from functional blocks of integrated circuits, e.g., core logic area, being more active than other areas, e.g., the cache.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1 illustrates a cross-sectional view of an electronic assembly including a thermal management arrangement coupled to a semiconductor package, in accordance with an embodiment of the present invention;

FIG. 2 illustrates a top-view of the channels of a channel structure, in accordance with an embodiment of the present invention;

FIGS. 3a-3c illustrate top-views of the channels of a channel structure with flow inhibitors placed in various positions, in accordance with embodiments of the present invention;

FIG. 4 illustrates a top-view of a channel structure having flow inhibitors coupled to both the high and the low heat flux channels, in accordance with an embodiment of this invention;

FIGS. 5a-5c illustrate longitudinal views of flow cross-sectional areas of channels with various flow inhibitor configurations, in accordance with embodiments of the present invention; and

FIG. 6 illustrates a system employing a thermal management arrangement, in accordance with an embodiment of the present invention.

### DETAILED DESCRIPTION

A method, apparatus, and system for adjusting flow distributions through channels of a thermal management arrangement for cooling a semiconductor package is disclosed herein. In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the embodiments of the present invention. It should also be noted that directions and references (e.g., top, bottom, back, front, etc.) might be used to facilitate the discussion of the drawings, however they are not intended to restrict the application of the embodiments of this invention. Therefore, the following detailed description is not to be taken in a limiting sense and the scope of the embodiments of the present invention are defined by the appended claims and their equivalents.

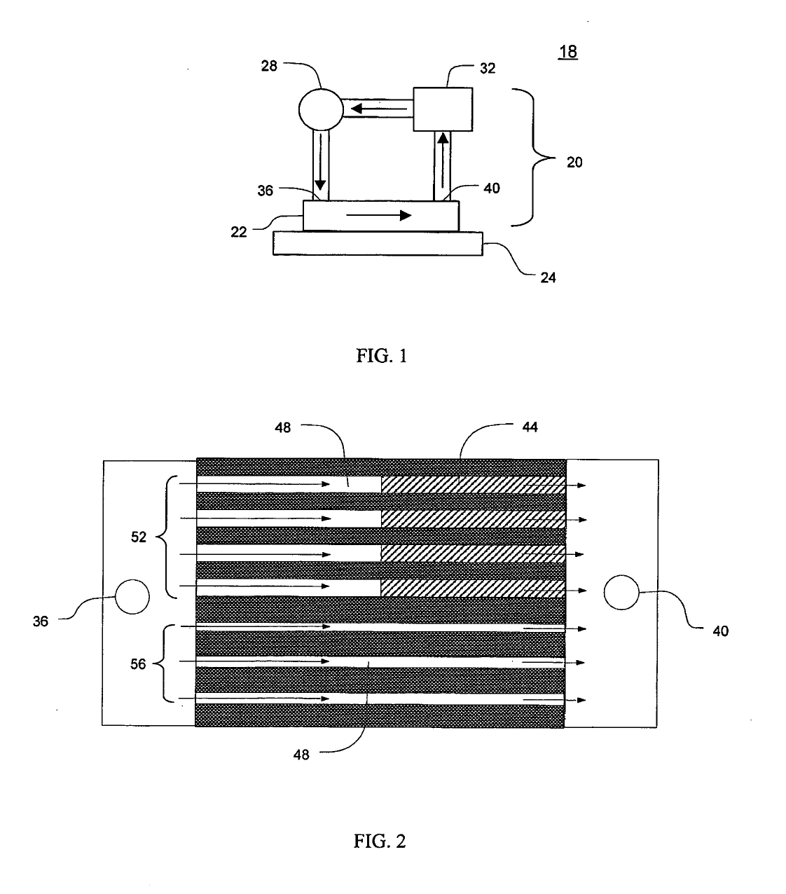

FIG. 1 illustrates a cross-sectional view of an electronic assembly 18 including a thermal management arrangement 20 in accordance with an embodiment of this invention. In this embodiment the thermal management arrangement 20 may be coupled to a semiconductor package 24 in order to facilitate the management of excess heat generated by the semiconductor package 24. The thermal management arrangement may include a channel structure 22 having a number of channels designed to thermally couple a cooling fluid to the semiconductor package 24 to allow the cooling fluid to absorb at least a portion of the excess heat generated by the semiconductor package 24. Furthermore, the channels may be designed to adapt fluid flows to respective heat flux areas that may correspond to areas of varying heat output by the semiconductor package 24. In various embodiments the channel structure 22 may include, but is not limited to, a cold plate, an integrated heat spreader, or part of the semiconductor package 24 itself. The materials and design of the channel structure 22 are not restricted beyond what it takes to accommodate such channels. In one embodiment the channel structure 22 may be made of a conductive material (e.g., copper).

In one embodiment, a thermal interface material may be used to couple the semiconductor package 24 and the channel structure 22 together in order to decrease the thermal resistance in the pathway between the semiconductor package 24 and the fluid. Examples of types of thermal interface materials include, but are not limited to, a thin layer of solder paste, phase-change materials, thermal adhesives (e.g., a highly filled epoxy or acrylic), double-sided thermal tape, and thermal interface pads. In another embodiment the channel structure 22 may be coupled to an integrated heat spreader (not shown) that is thermally coupled to the semiconductor package 24.

In one embodiment a pump 28 may be used to create a pressure differential between an inlet 36 and an outlet 40 to facilitate the flow of the fluid through the channels. The fluid may absorb at least a portion of the excess heat dissipated from the semiconductor package 24 as it flows through the channels of the channel structure 22. The heated fluid may flow out of the outlet 40 and towards a remote heat exchanger 32. The excess heat may then be transferred to the remote heat exchanger 32, which could be any known or to be designed heat dissipation mechanism. In one embodiment the heat exchanger 32 may dissipate excess thermal energy from the cooling fluid and present the fluid to the pump 28 so that it may be reintroduced to the channel structure 22. Examples of the cooling fluid may include a gas (e.g., air) and a liquid (e.g., water, alcohol, perfluorinated liquids, etc.).

Various embodiments of this invention may include thermal management arrangements employing a variety of heat transfer techniques analogous to the heat transfer technique described in FIG. 1. For example, in one embodiment the thermal management arrangement may use mechanical refrigeration, such as a vapor-compression cycle. The vapor-compression cycle may include at least partially evaporating a liquid cooling fluid through a channel structure, similar to the channel structure 22 of FIG. 1. The at least partially evaporated cooling fluid may then enter a compressor where the pressure and temperature may be raised. The superheated cooling fluid may then move to a condenser (e.g., a heat exchanger) and discharge at least a portion of its heat. The fluid may then expand from the high-pressure level in the condenser to a low-pressure level through an expansion valve for reintroduction to the channels of the channel structure. Other embodiments may use other refrigeration processes including, but not limited to, absorption, steam-jet, and air cycles. Still other embodiments may use other heat transfer techniques in order to dissipate thermal energy absorbed by the cooling fluid and reintroduce the fluid to the channel structure.

In one embodiment the semiconductor package 24 could include an integrated circuit formed in a rectangular piece of semiconductor material called a chip or a die. Examples of the semiconductor material include, but are not limited to silicon, silicon on sapphire, and gallium arsenide. A die may include different areas with different levels of activity. The active area of the die, e.g., the core logic area, may output more excess heat than the more passive areas of the die, e.g., the cache. The two areas of the channel structure 22 that correspond to these different heat output areas may be referred to as a high heat flux area and a low heat flux area, respectively. While this embodiment discusses two heat output areas, other embodiments consistent with the scope of this invention may accommodate a number of heat output gradients of varying degrees over the surface of the die.

In one embodiment, the fluid flowing through channels which travel through the high heat flux area may result in different flow dynamics than fluid flowing through channels which travel only through the low heat flux area. Prior art arrangements not accounting for these variant flow dynamics may result in undesired and/or unintended flow distributions over the range of channels. For example, liquid flowing through the high heat flux area may begin to boil in two-phase flow. As liquid turns into vapor, the vapor has to accelerate to satisfy the law of conservation of mass. This acceleration of vapor may lead to large pressure drops in the channels in the high heat flux area. Because the pressure drop between the common inlet and the outlet is fixed, the greater pressure drop in the high heat flux channels may lead to a decrease in the volumetric flow rate through those channels along with a corresponding increase in the volumetric flow rate through the low heat flux channels. This decrease in flow rate through the high heat flux channels may reduce the heat transfer coefficient, thereby potentially compromising the ability to transfer heat from the area that most needs it.

FIG. 2 illustrates a top-view of channels of the channel structure 22, in accordance with an embodiment of this invention. In this embodiment the channels may be adapted to address the varying flow dynamics that may take place due to varying heat fluxes. In one embodiment, the channels may be arranged substantially parallel to one another such that fluid entering from the common inlet 36 will travel a parallel course through each of the channels and exit through the common outlet 40. The high heat flux channels 52 may have at least a portion of the channel in a high heat flux area 44, while the low heat flux channels 56 may be situated in a low heat flux area 48. In other embodiments, the designation of whether a channel is a low or high heat flux channel may relate to the amount of heat through the channel, which may not necessarily correspond to the amount of the channel in each heat flux area.

In one embodiment the fluid flowing through the high heat flux channels 52 may experience two-phase flow. As mentioned earlier, two-phase flow may occur when heat from the semiconductor package 24 transforms a liquid into a vapor. As the vapor flows away from the semiconductor package 24 towards the heat exchanger 32 it may cool and condense back into liquid, which may result in a release of its latent heat of vaporization. In one embodiment the condensation may begin to occur immediately following the high heat flux area. Two-phase cooling has been shown to provide higher heat transfer coefficients and lower thermal resistances than single-phase cooling, potentially increasing the total amount of heat transfer away from the semiconductor package 24.

As the liquid in the high heat flux channels 52 experiences two-phase flow, the pressure drop across those channels may tend to increase. However, in this embodiment the low heat flux channels 56, experiencing only single-phase flow, may be structurally adapted in a manner to complement the high heat flux channels 52. In one embodiment, the design of the low heat flux channels 56 may artificially increase the pressure drop over those channels in order to counterbalance the pressure drop resulting from the two phase flow through the high heat flux channels 52. Artificially increasing the pressure drop for the low heat flux channels 56 may help to maintain sufficient flows through the high heat flux channels 52.

In one embodiment, the low heat flux channels 56 may be structurally adapted to complement the high heat flux channels 52 by having a reduced flow cross-sectional area to artificially increase the pressure drop over those channels. Adjusting the flow cross-sectional areas, and thereby the pressure drop, of the low heat flux channels 56 may facilitate adapting the fluid flow distributions to the respective heat fluxes. For example, in one embodiment the low heat flux channels 56 may be structurally adapted to complement the high heat flux channels 52 in a manner such that the flow distributions are approximately equal to one another. Another embodiment may adapt the low heat flux channels 56 such that the fluid has a higher flow rate through the high heat flux channels 52, thereby potentially dissipating more heat from the high heat flux area.

Although the above embodiment illustrates channels being structurally adapted in two manners to correspond to two heat flux areas, other embodiments may include channels being adapted in any number of manners to correspond with any number of heat flux areas. For example, one embodiment may have transitional channels to correspond to a heat flux somewhere in between the high and the low heat fluxes. Various embodiments may also include one heat flux area having more than one corresponding channel structure resulting in more than one flow rate.

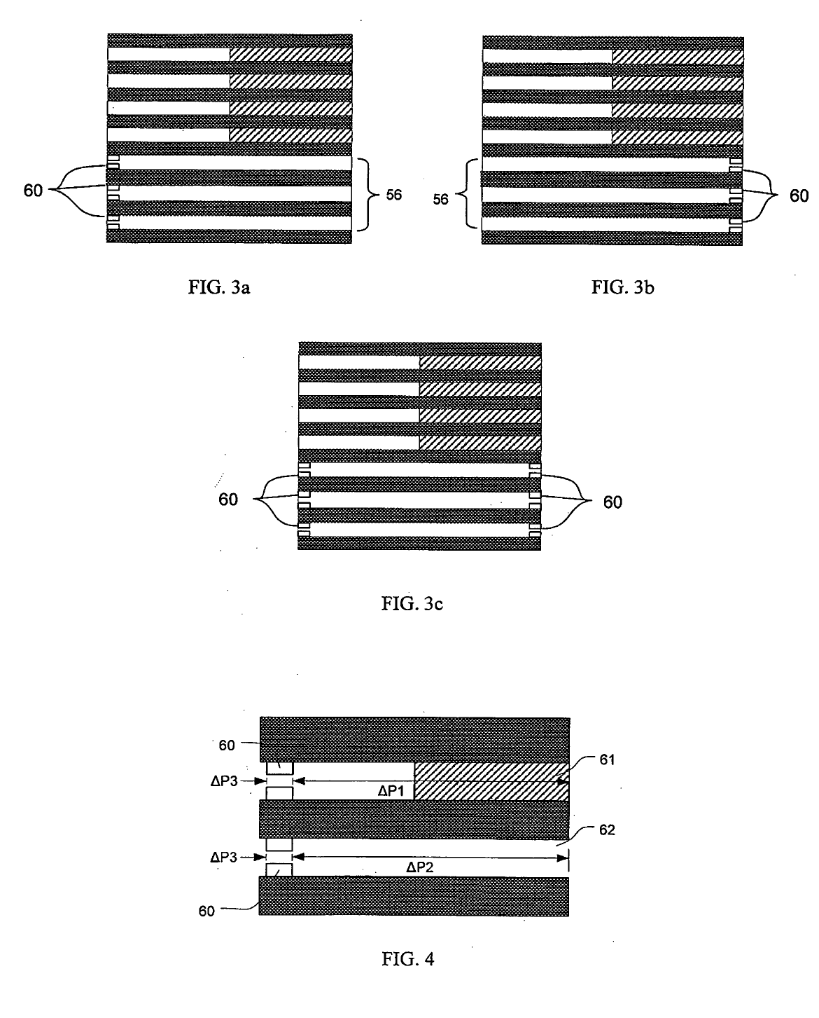

FIGS. 3a-3c illustrate embodiments having flow inhibitors 60 being used to selectively reduce the flow cross-sectional areas of certain channels. In one embodiment, depicted in FIG. 3a, the flow inhibitors 60 may be proximally disposed near inputs of the low heat flux channels 56. These flow inhibitors may facilitate the adjustment of the pressure drop through the low heat flux channels 56, thereby assisting in the adaptation of the fluid flow rates to particular heat flux areas of the thermal management arrangement 20. The pressure drop across an orifice for single-phase flow is given by:

$$Δ p = {( \frac{V}{KA} )}^{2} \frac{ρ}{2} \qquad Equation ( 1 )$$

where Δp is the pressure drop across the orifice; K is the flow coefficient; A is the flow cross-sectional area defined by the flow inhibitor; V is the volumetric flow rate and ρ is the density of the fluid. Equation (1) shows that the pressure drop increases with the decreasing area of the throat area (e.g., the flow cross-sectional area). This may assist in the adjustment of the dimensions of the flow inhibitors 60 in order to achieve the desired pressure drops through the low heat flux channels 56. Therefore, the flow inhibitors may be used to provide a calculated restriction on the flow cross-sectional areas of the low heat flux channels that may result in the desired flow rates.

As generally depicted in FIG. 3, the dimensions of both the high heat flux and the low heat flux channels may be approximately the same. In one embodiment, the use of modular flow inhibitors may provide retrofitting to existing channel designs. Additionally, selectively adding flow inhibitors to channels may provide the flexibility to allow the channels of mass-produced channel structures to be adapted to the thermal gradients of a particular die. Furthermore, in various embodiments flow inhibitors may allow channels that are otherwise constrained by manufacturing limitations to provide smaller flow cross-sectional areas.

FIGS. 3b and 3c illustrate two embodiments including various placements of the flow inhibitors 60. In FIG. 3b the flow inhibitors 60 are proximally disposed near the outputs of the low heat flux channels 56. In FIG. 3c the flow inhibitors 60 are coupled near both the inputs and the outputs of the low heat flux channels 56. Various embodiments may use alternative placements of the flow inhibitors, e.g., somewhere between the input and the output.

FIG. 4 illustrates flow inhibitors 60 being placed in both a high heat flux channel 61 and a low heat flux channel 62 in accordance with an embodiment of the present invention. In this embodiment a fluid flowing through the high heat flux channel 61 may experience a pressure drop of ΔP1 due in part to two-phase flow. A fluid flowing through the low heat flux channel 62 may experience a lower pressure drop ΔP2 due to the single-phase flow. In a prior art device, these pressure drops may respectively define the pressure drops for the entire channel. In such prior art devices, the resulting ratio of ΔP1/ΔP2 may result in a relatively large amount of the fluid flowing through the low heat flux channel 62 as opposed to the high heat flux channel 61, as discussed above. However, this embodiment may reduce the unequal flow distribution by adding an additional pressure drop ΔP3 to both the high and low heat flux channels 61 and 62. This additional pressure drop ΔP3 may be the result of flow inhibitors 60 coupled to the channels 61 and 62. Therefore, the resulting ratio of the total pressure drop of the channels may be less than the ratio without the flow inhibitors 60. This relationship may be summarized by the following equation:
(ΔP1+ΔP3)/(ΔP2+ΔP3)<ΔP1/ΔP2 Equation (2)

As the ratio of the pressure drops between the channels 61 and 62 is reduced the relative discrepancy between the flow distributions may also be reduced. In one embodiment ΔP3 may be orders of magnitude larger than the pressure drops ΔP1 and ΔP2, which could result in the ratio of the total pressure drops of the channels 61 and 62 being much less than the ratio of the pressure drops without the flow inhibitors 60. Embodiments having flow inhibitors coupled to both the high heat flux channels 61 and the low heat flux channels 62 may be useful in embodiments where it is difficult to isolate and compartmentalize the low and high heat flux areas of the channel structure.

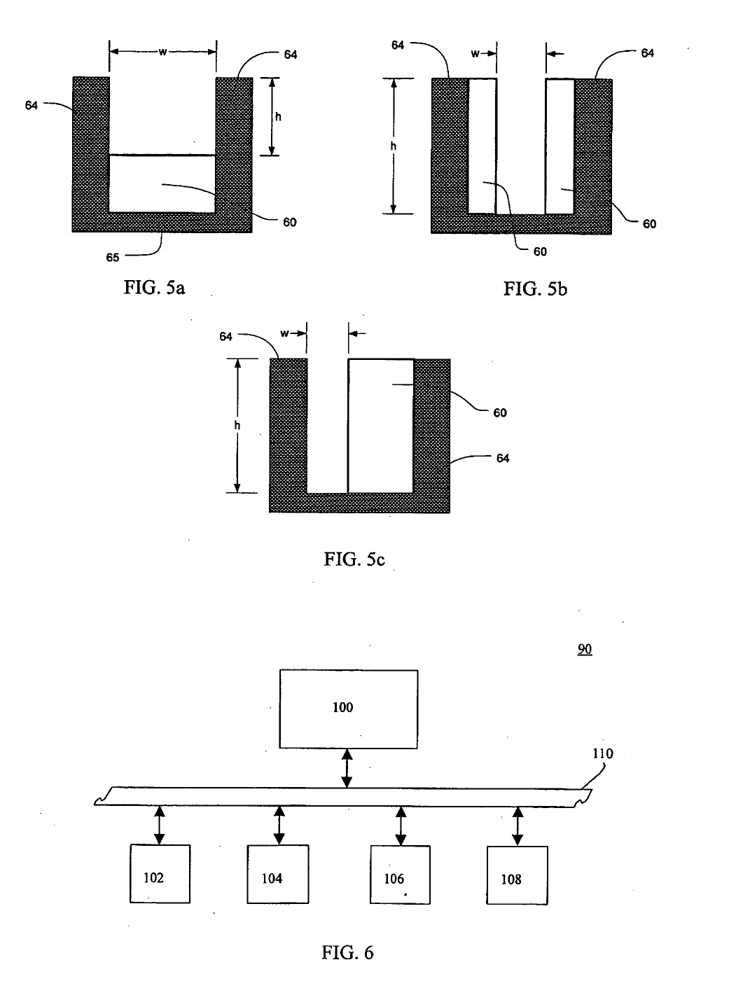

FIGS. 5a-5c illustrate longitudinal views of flow cross-sectional areas of channels with various flow inhibitor configurations, in accordance with embodiments of the present invention. FIG. 5a illustrates one flow inhibitor 60 being coupled to the bottom of the channel 65, in accordance with one embodiment of this invention. In this embodiment, the flow cross-sectional area, may be defined by the height of the flow area, h, times the width of the flow area, w. FIG. 5b illustrates flow inhibitors 60 being coupled to both of the channel walls 64, in accordance with another embodiment. FIG. 5c illustrates an embodiment with a flow inhibitor 60 coupled to only one channel wall 64. Various embodiments within the scope of this invention may incorporate a different number and/or placement of flow inhibitors 60.

Referring to FIG. 6, there is illustrated one of many possible systems in which embodiments of the present invention may be used. The electronic assembly 100 may be similar to the electronic assembly 18 depicted above in FIG. 1. In one embodiment, the electronic assembly 100 may include a microprocessor. In an alternate embodiment, the electronic assembly 100 may include an application specific IC (ASIC). Integrated circuits found in chipsets (e.g., graphics, sound, and control chipsets) may also be packaged in accordance with embodiments of this invention.

For the embodiment depicted by FIG. 6, the system 90 may also include a main memory 102, a graphics processor 104, a mass storage device 106, and/or an input/output module 108 coupled to each other by way of a bus 110, as shown. Examples of the memory 102 include but are not limited to static random access memory (SRAM) and dynamic random access memory (DRAM). Examples of the mass storage device 106 include but are not limited to a hard disk drive, a compact disk drive (CD), a digital versatile disk drive (DVD), and so forth. Examples of the input/output module 108 include but are not limited to a keyboard, cursor control arrangements, a display, a network interface, and so forth. Examples of the bus 110 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

1. A thermal management arrangement comprising:
a first channel structurally adapted in a first manner to provide a first fluid flow at a first flow rate for a first area of a semiconductor package having a first heat flux; and
a second channel structurally adapted in a second manner, complementary to the first manner, to provide a second fluid flow at a second flow rate approximately equal to or less than the first flow rate, for a second area of the semiconductor package having a second heat flux, lower than the first heat flux.

2. The thermal management arrangement of claim 1, wherein the second channel includes a flow inhibitor.

3. The thermal management arrangement of claim 2, wherein the flow inhibitor is proximally disposed near an input end of the second channel.

4. The thermal management arrangement of claim 1, wherein the first and second channels are coupled to a common inlet.

5. The thermal management arrangement of claim 1, wherein the first and second channels are coupled to a common outlet.

6. The thermal management arrangement of claim 5, further comprising:
a pump coupled to a common inlet to which the first and second channels are coupled, to provide the first and second fluid flows; and
a heat exchanger coupled to the common outlet to remove heat from the first and second fluid flows.

7. The thermal management arrangement of claim 1, wherein the first and second channels are substantially parallel to one another.

8. The thermal management arrangement of claim 1, further comprising a third channel structurally adapted to provide a third fluid flow at a third flow rate to the first area, and the second channel is structurally adapted to complement the first and third channels, with the second flow rate being approximately less than or equal to the first and third flow rates.

9. The thermal management arrangement of claim 1, further comprising a third channel structurally adapted to provide a third fluid flow at a third flow rate to the second area, and the second and third channels are structurally adapted to complement the first channel, with the second and third flow rates being approximately less than or equal to the first flow rate.

10. A thermal management arrangement comprising:
a first channel to provide a first fluid flow for a first heat flux area of a semiconductor package;
a second channel to provide a second fluid flow for a second heat flux area of the semiconductor package; and
first and second flow inhibitors respectively coupled to the first and second channels, to facilitate a distribution of at least a portion of an influent fluid flow into the first and second fluid flows.

11. The thermal management arrangement of claim 10, wherein
the first fluid flow has a first pressure drop through the first channel;
the second fluid flow has a second pressure drop through the second channel that is less than the first pressure drop; and
the first and second flow inhibitors being adapted to provide additional pressure drops to the first and the second pressure drops resulting in the first channel having a third pressure drop and the second channel having a fourth pressure drop.

12. The thermal management arrangement of claim 11, wherein the ratio of the first pressure drop to the second pressure drop is greater than the ratio of the third pressure drop to the fourth pressure drop.

13. The thermal management arrangement of claim 11, wherein the first fluid flow is two-phase flow through at least a portion of the first channel.

14. The thermal management arrangement of claim 13, wherein the second fluid flow is single-phase flow.

15. A method of operating a thermal management arrangement comprising:
providing a first fluid flow with a first flow rate through a first channel having at least a first portion thermally coupled to a first area of a semiconductor package, the first fluid flow experiencing two-phase flow through at least part of the first portion of the first channel; and
providing a second fluid flow with a second flow rate through a second channel having at least a second portion thermally coupled to a second area of the semiconductor package, the second fluid flow experiencing single-phase flow, the second flow rate being approximately equal to or less than the first flow rate.

16. The method of claim 15, further comprising:
providing a first pressure drop across the first channel; and
providing a second pressure drop across the second channel, the second pressure being approximately equal to or less than the first pressure drop.

17. The method of claim 16, wherein providing a second pressure drop approximately equal to or less than the first pressure drop is done at least in part by providing the second fluid flow through a restricted flow cross-sectional area in the second channel.

18. The method of claim 17, wherein the restricted flow cross-sectional area in the second channel comprises a flow inhibitor.

19. A system comprising:
a semiconductor package having an integrated circuit, a first area having a first heat output, and a second area having a second heat output less than the first heat output;
a thermal management arrangement to at least facilitate the dissipation of heat from the semiconductor package, the thermal management arrangement including
a first channel, thermally coupled with the first area and structurally adapted in a first manner to provide a first fluid flow at a first flow rate; and
a second channel, thermally coupled with the second area and structurally adapted in a second manner, complementary to the first manner, to provide a second fluid flow at a second flow rate approximately equal to or less than the first flow rate; and
a mass storage device coupled to the semiconductor package.

20. The system of claim 19, further comprising:
a dynamic random access memory coupled to the integrated circuit; and
an input/output interface coupled to the integrated circuit.

21. The system of claim 20, wherein the input/output interface comprises a networking interface.

22. The system of claim 19, wherein the second channel includes a flow inhibitor.

23. The system of claim 19, further comprising:
a pump coupled to a common inlet to which the first and second channels are coupled, to provide the first and second fluid flows; and
a heat exchanger coupled to a common outlet to which the first and second channels are coupled, to remove heat from the first and second fluid flows.

24. The system of claim 19, wherein the first area of the semiconductor package includes core logic of the integrated circuit and the second area of the semiconductor package includes a cache of the integrated circuit.

25. The system of claim 19, wherein the integrated circuit is a processor.

26. The system of claim 25, wherein the system is a selected one of a group consisting of a set-top box, a media-center personal computer, and a digital versatile disk player.

27. A system comprising:
a semiconductor package having an integrated circuit, a first area having a first heat output, and a second area having a second heat output less than the first heat output; and
a thermal management arrangement to at least facilitate the dissipation of heat from the semiconductor package, the thermal management arrangement including
a first channel to thermally couple a first fluid flow with the first area;
a second channel to thermally couple a second fluid flow with the second area; and
first and second flow inhibitors respectively coupled to the first and second channels, to facilitate a distribution of at least a portion of an influent fluid flow into the first and second fluid flows; and
a mass storage device coupled to the semiconductor package.

28. The system of claim 27, wherein the integrated circuit is a processor.

29. The system of claim 28, wherein the system is a selected one of a group consisting of a set-top box, a media-center personal computer, and a digital versatile disk player.
